(19) United States
(12) Patent Application Publication
(10) Pub. No.: US 2019/0348964 A1
(43) Pub. Date: Nov. 14, 2019

(54) SURFACE ACOUSTIC WAVE ELEMENT PACKAGE AND MANUFACTURING METHOD THEREOF

(71) Applicant: WISOL CO., LTD., Gyeonggi-do (KR)

(72) Inventors: Jong-Soo Ha, Gyeonggi-do (KR); Ji-Ho Kim, Gyeonggi-do (KR)

(21) Appl. No.: 16/461,465

(22) PCT Filed: Nov. 15, 2017
(86) PCT No.: PCT/KR2017/012925

§ 371 Date: May 16, 2019

(30) Foreign Application Priority Data
Nov. 17, 2016 (KR) 10-2016-0153157

(51) Int. Cl. H03H 9/05; H03H 3/08; H03H 9/10; H03H 9/145; H03H 9/25; C09J 9/02

(52) U.S. Cl. CPC H03H 9/0585; H03H 3/08; C09J 9/02; H03H 9/145; H03H 9/25; H03H 9/1085

(57) ABSTRACT

A surface acoustic wave element package according to the present invention includes: a surface acoustic wave element including a piezoelectric substrate, and including an IDT electrode and a plurality of electrodes formed on the piezoelectric substrate; a substrate for a package, the substrate for a package being provided with a plurality of terminals that respectively correspond to the plurality of electrodes, and having the surface acoustic wave element mounted thereon; and a cured nano-silver paste electrically connecting the plurality of electrodes to the plurality of terminals, respectively.

### TECHNICAL FIELD

The present invention relates to a surface acoustic wave (SAW) device package and a method of manufacturing the SAW device package.

### BACKGROUND ART

As the communications industry has developed, wireless-communication products are miniaturized, improve in qualities, and become multifunctional gradually. In accordance with this tendency, miniaturization and multifunction of components used in a wireless-communication product, for example, a filter, a duplexer, and the like are required.

As an example of such components, as shown in FIG. 1, a surface acoustic wave (SAW) device includes a piezoelectric substrate 1 which is a piezoelectric single-crystal bare chip, a pair of interdigital transducer (IDT) electrodes 2 which are formed on a top surface thereof to have a comb shape and face each other, and input and output electrodes 3 and 4 connected thereto.

When an electrical signal is applied through the input electrode 3, a piezoelectric distortion occurs due to a piezoelectric effect by an overlapped electrode length between the IDT electrodes 2 facing each other such that an SAW to be transferred to the piezoelectric substrate 1 occurs due to the piezoelectric distortion and is converted into an electrical signal and output through the output electrode 4. Here, only an electrical signal in a certain frequency band determined by a variety of factors such as intervals, a width and length, and the like of the IDT electrodes 2 is filtered.

Since device properties are determined by the width, length, intervals, and the like of the IDT electrodes 2 formed on the piezoelectric substrate 1 of the SAW device, when the IDT electrodes 2 has damage or are smeared with micro-sized foreign substances such as dust or dirt, device properties change. Accordingly, a variety of shapes of structures are necessary to protect an SAW occurrence area of the SAW device such as the IDT electrodes 2 from an external environment.

FIG. 2 illustrates an example of a structure of an existing SAW device package for protecting the IDT electrodes 2 and the like of the SAW device from an external environment.

As shown in FIG. 2, the existing SAW device package includes a ceramic substrate 7, on which the SAW device is mounted using a flip chip bonding method and which includes terminals 6 corresponding to the input and output electrodes 3 and 4, bumps 5 joined to the input and output electrodes 3 and 4 and the terminals 6, and a molding portion 8 which covers the SAW device. A space for the SAW occurrence area such as the IDT electrodes 2 and the like is provided by the bumps 5, and the molding portion 8 performs a function of protecting the SAW occurrence area from an external environment.

In order to manufacture the SAW device package, first, the bumps 5 are formed using gold (Au) or an Au alloy on the input and output electrodes 3 and 4 of the SAW device and then the SAW device, on which the bumps 5 are formed, is mounted on the ceramic substrate 7 such that the bumps 5 and the terminals 6 are joined to each other. In a process of forming the bumps 5 on the electrodes 3 and 4 and a process of joining the bumps 5 to the terminals 6 as described above, ultrasonic bonding or thermosetting bonding is used which has disadvantages such as a complicated process and a high cost.

Also, generally, the SAW device package is manufactured as a wafer level package and goes through a dicing process. Here, the ceramic substrate 7 is easily brittle in the dicing process due to high brittleness thereof such that the dicing process is complicated and an increase in cost is caused.

### DISCLOSURE

### Technical Problem

The present invention is directed to providing a surface acoustic wave (SAW) device package capable of being manufactured through a simple and inexpensive process without ultrasonic bonding or thermosetting bonding and a method of manufacturing the same.

The present invention is also directed to providing an SAW device package capable of reducing a cost of a dicing process and a method of manufacturing the same.

### Technical Solution

One aspect of the present invention provides a surface acoustic wave (SAW) device package including an SAW device which includes a piezoelectric substrate and includes an interdigital transducer (IDT) electrode and a plurality of electrodes, which are formed on the piezoelectric substrate, a package substrate which includes a plurality of terminals respectively corresponding to the plurality of electrodes and on which the SAW device is mounted, and a cured nano-silver paste which electrically connects the plurality of electrodes to the plurality of terminals respectively.

A partition, which surrounds each of the terminals and surrounds the nano-silver paste, may be formed on the package substrate.

The partition may be formed of an insulating material.

The SAW device package may further include a molding portion which covers the SAW device. Here, the partition may surround each of the plurality of terminals and the nano-silver paste simultaneously while surrounding a space, in which the IDT electrode is disposed, in order to prevent a molding material forming the molding portion from passing through the space in which the IDT electrode is disposed.

The package substrate may be an organic substrate.

Another aspect of the present invention provides a method of manufacturing an SAW device package. The method includes preparing an SAW device package which includes a piezoelectric substrate and includes an IDT electrode and a plurality of electrodes, which are formed on the piezoelectric substrate, preparing a package substrate which includes a plurality of terminals respectively corresponding to the plurality of electrodes, applying a nano-silver paste to each of the plurality of terminals of the package substrate, placing the SAW device on the package substrate such that the plurality of electrodes come into contact with the nano-silver paste, and curing the nano-silver paste by applying heat thereto.

The method may further include forming a partition, which surrounds each of the plurality of terminals, on the package substrate. Here, the applying of the nano-silver paste may include applying the nano-silver paste such that the nano-silver paste is surrounded by the partition.

The method may include forming a molding portion which covers the SAW device. Here, the forming of the partition may include forming the partition to surround each of the plurality of terminals simultaneously while surrounding a space, in which the IDT electrode is disposed, in order to prevent a molding material forming the molding portion from passing through the space in which the IDT electrode is disposed.

### Advantageous Effects

According to the present invention, electrodes of a surface acoustic wave (SAW) device are electrically connected to terminals of a package substrate using a nano-silver paste such that an SAW device package may be manufactured through a simple process and a cost thereof may be reduced.

Also, since the package substrate is formed of an organic substrate, a dicing process may be simplified so as to reduce a cost thereof.

### DESCRIPTION OF DRAWINGS

FIG. 1 illustrates an example of a surface acoustic wave (SAW) device.

FIG. 2 illustrates an example of a structure of an existing SAW device package.

FIG. 3 illustrates an example of an SAW device and a package substrate, which are prepared in a method of manufacturing an SAW device package according to one embodiment of the present invention.

FIG. 4 illustrates an example of a shape in which partitions are formed on the package substrate.

FIG. 5 illustrates an example of a plan view in which partitions are formed on the package substrate.

FIG. 6 illustrates an example of a plan view in which partitions are formed on the package substrate.

FIG. 7 illustrates a shape in which a nano-silver paste is applied to each of terminals of the package substrate.

FIG. 8 illustrates a shape in which the SAW device is disposed on the package substrate having terminals to which the nano-silver pastes are applied.

FIG. 9 illustrates a structure of the SAW device package according to one embodiment of the present invention which includes a cured nano-silver paste.

FIG. 10 illustrates a structure of the SAW device package according to one embodiment of the present invention which includes a molding portion.

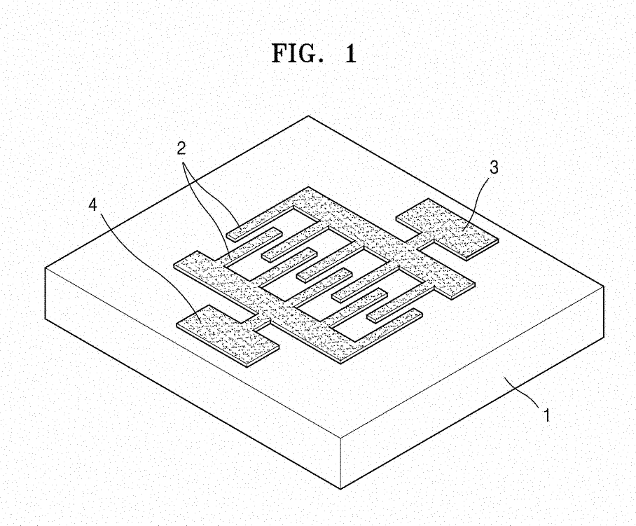

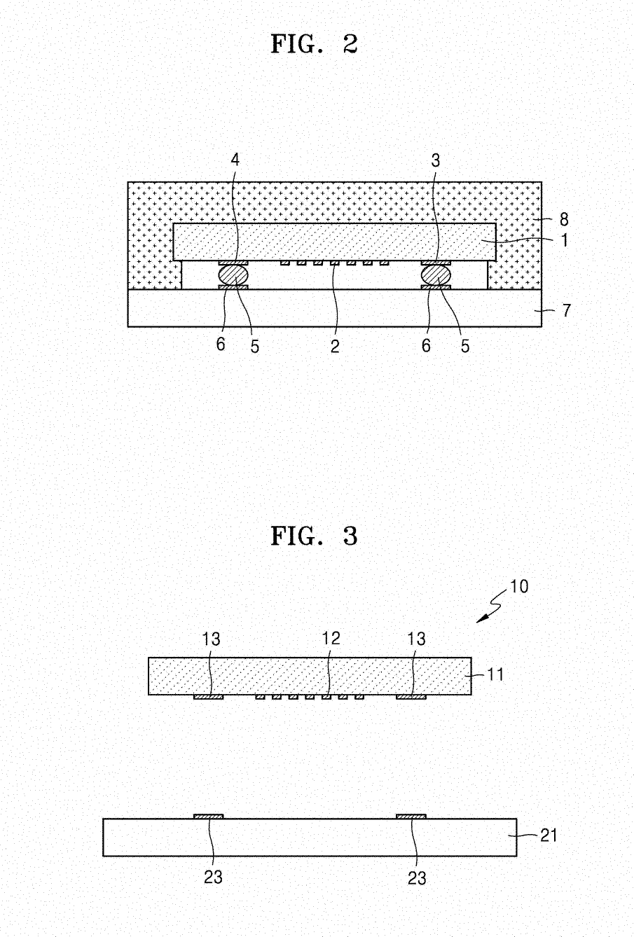

### MODES OF THE INVENTION

Hereinafter, exemplary embodiments of the present invention will be described in detail with reference to the attached drawings. In the following description and the attached drawings, substantially like elements are referred to as like reference numerals and an overlapping description will be omitted. Also, in the description of the present invention, a detailed description on well-known functions or components of the related art will be omitted when it is deemed to obscure the essence of the present invention.

FIGS. 3 to 10 are views illustrating a surface acoustic wave (SAW) device package and a method of manufacturing the same according to one embodiment of the present invention.

First, as shown in FIG. 3, an SAW device 10, which includes a piezoelectric substrate 11 and an interdigital transducer (IDT) electrode 12 and a plurality of electrodes 13 formed on the piezoelectric substrate 11, is prepared and a package substrate 21 which includes a p plurality of terminals 23 respectively corresponding to the plurality of electrodes 13 are provided on a top surface is prepared.

Generally, the SAW device 10 generally includes two or more electrodes 13, and for example, may include input and output electrodes, a ground electrode, and the like. The electrodes 13 and the terminals 23 may be plated with gold or copper.

The package substrate 21 may be, for example, an organic substrate such as a printed circuit board (PCB) having FR4 and the like. Since the organic substrate has lower fragility than that of a ceramic substrate and is not broken well, when it is manufactured as a wafer level package, a dicing process is simple such that a cost consumed for the dicing process may be reduced.

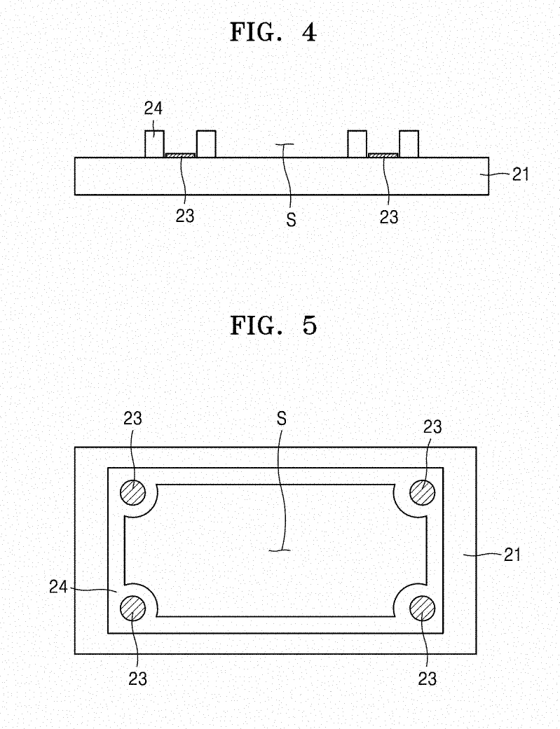

Next, referring to FIG. 4, on the package substrate 21, the partition 24 which surrounds the plurality of terminals 23 simultaneously while surrounding a space S in which the IDT electrode 12 is disposed.

As described below, the partition 24 performs a function of preventing a nano-silver paste 25, which is applied to each of the terminals 23, from flowing out from the terminals 23, performs a function of preventing a molding material, which forms a molding portion 40 from passing through the space S in which the IDT electrode 12 is disposed, and performs a function of a support which supports the SAW device 10 to be disposed on the package substrate 21. Accordingly, the partition 24 may have a height corresponding to a height of a nano-silver paste which will be filled therein and corresponding to a height at which the SAW device 10 is located with respect to the package substrate 21.

FIG. 5 illustrates a plan view in which the partition 24 is formed on the package substrate 21 including four terminals 23. As shown in the drawing, the partition 24 is formed to surround the terminals 23 while surrounding the space S in which the IDT electrode 12 is disposed.

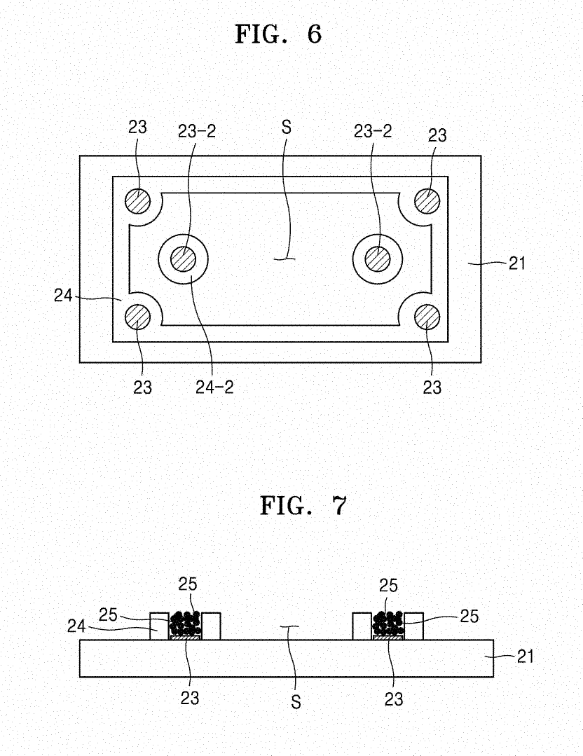

FIG. 6 illustrates a plan view in which partitions 24 and 24-2 are formed on the package substrate 21 including six terminals 23 and 23-2. The partition 24 is formed to surround the terminals 23 while surrounding the space S in which the IDT electrode 12 is disposed like the shown in FIG. 5. Also, due to the additional terminals 23-2, the partition 24-2, which surrounds the terminals 23-2, is further formed.

The above-described partition 24 is formed of an insulating material, and for example, may be formed of a solder resist. The partition 24 may be formed by being photosensitive-coated or photosensitive-film laminating and using a photolithography process.

Meanwhile, in the embodiment of the present invention, the package substrate 21 is formed of an organic substrate not to be fragile. However, since a ceramic substrate is inadequate for forming the partition 24 using a solder resist through a photolithography process due to material properties thereof, the package substrate 21 is formed of an organic substrate to effectively form the partition 24. That is, an organic substrate is used for the package substrate 21 such that the above-described partition 24 may be effectively formed through a photolithography.

Next, referring to FIG. 7, the nano-silver paste 25 is applied to each of the terminals 23 of the package substrate 21 to be surrounded by the partition 24. The nano-silver paste is a material generally used for a conductive adhesive or an electronic ink and is formed by mixing nano-meter silver particles, micro-meter silver particles, a resin for maintaining a certain level of viscosity at room temperature, and other additives such as a solvent and the like.

The nano-silver paste 25 may be applied to the terminals 23 of the package substrate 21 through a very simple printing process. Meanwhile, since the nano-silver paste 25 has fluidity at room temperature, it may flow out from the terminals 23 when the partition 24 is not present. Accordingly, the partition 24 performs a function of preventing the nano-silver paste 25, which is applied to each of the terminals 23, from flowing out from the terminals 23.

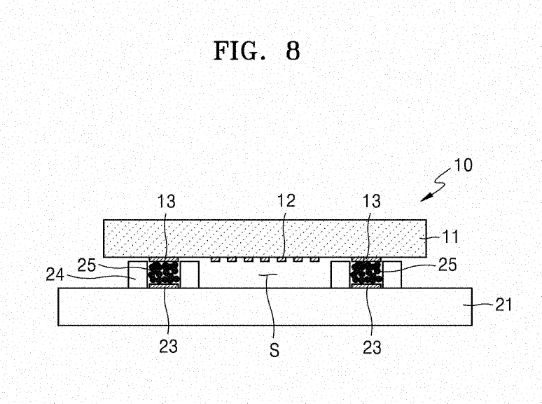

Referring to FIG. 8, the SAW device 10 is placed on the package substrate 21 such that the electrodes 13 and the nano-silver paste 25 on the corresponding terminals 23 come into contact with each other. Since the nano-silver paste 25 has fluidity at room temperature as described above, the nano-silver paste 25 before being cured has a difficulty in adequately supporting the SAW device 10 and may flow out from the terminals 23 due to a weight of the SAW device 10. Accordingly, in the embodiment of the present invention, the partition 24 is formed to surround each of the terminals 23 such that the SAW device 10 may be supported by the partition 24.

Heat is applied to the nano-silver paste 25 using, for example, a method of inserting a structure, in which the SAW device 10 is placed on the package substrate 21 as shown in FIG. 8, into a heating chamber. Here, for example, heat at a temperature from about 150° C. to 200° C. may be applied for about 30 to 90 minutes. Then, the nano-silver paste 25 is cured and joined to the electrodes 13 and the terminals 23 such that the electrodes 13 of the SAW device 10 and the terminals 23 of the package substrate 21 are electrically connected to each other through the cured nano-silver paste 25.

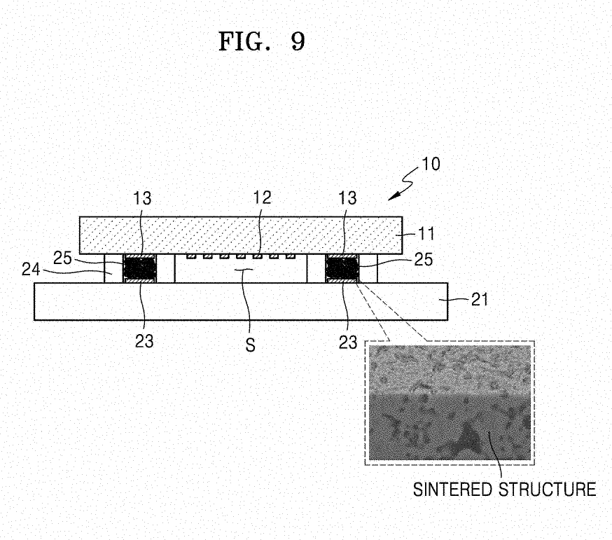

FIG. 9 illustrates a structure of the SAW device package in which the electrodes 13 of the SAW device 10 and the terminals 23 of the package substrate 21 are electrically connected through the cured nano-silver paste 25. FIG. 9 illustrates a partial enlarged view of the cured nano-silver paste 25 in which electrical connection is formed by a sintered structure in which nano-meter silver particles and micrometer silver particles stick to each other due to heat.

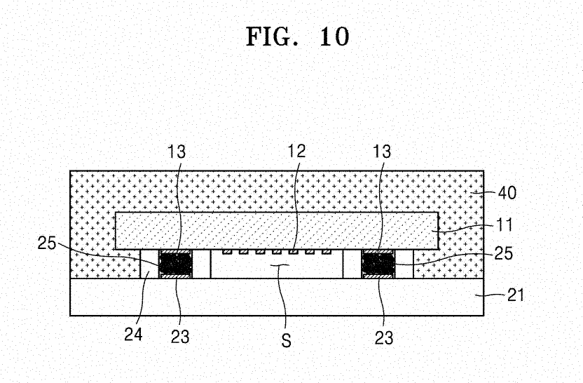

Next, referring to FIG. 10, the molding portion 40, which covers the SAW device 10, is formed using a molding material. As the molding material, materials such as an epoxy film, metal, ceramic, and the like may be used. Except metal, ceramic, and the like, a flexible molding material such as an epoxy film may pass through the space S in which the IDT electrode 12 is disposed when the partition 24 is not present. That is, when a molding material, which forms the molding portion 40, is a flexible material, the partition 24 performs a function of preventing the molding material from passing through the space S in which the IDT electrode is disposed.

According to the above-described present invention, the nano-silver paste is used as means for electrically connecting the electrodes 13 of the SAW device 10 to the terminals 23 of the package substrate 21 such that the SAW device package may be manufactured through very simple and less-expensive processes of printing and heating nano-silver paste without ultrasonic bonding or thermosetting bonding.

The present invention may be more effectively embodied through the partition 24 which surrounds each of the terminals 23 of the package substrate 21.

In addition, an organic substrate is used as the package substrate 21 such that not only cost necessary for a dicing process may be reduced rather than a ceramic substrate but also the partition 24 may be more effectively formed.

The exemplary embodiments of the present invention have been described above. It can be understood by one of ordinary skill in the art that modifications may be made without departing from the essential features of the present invention. Therefore, the described embodiments should be considered in a descriptive point of view not in a limitative one. The scope of the present invention is defined by the claims not by the above description, and it should be understood that all differences within the equivalent scope thereof are included in the present invention.

1. A surface acoustic wave (SAW) device package comprising:
a SAW device which comprises a piezoelectric substrate and comprises an interdigital transducer (IDT) electrode and a plurality of electrodes, which are formed on the piezoelectric substrate;
a package substrate which comprises a plurality of terminals respectively corresponding to the plurality of electrodes and on which the SAW device is mounted; and
a cured nano-silver paste which electrically connects the plurality of electrodes to the plurality of terminals respectively.

2. The SAW device package of claim 1, wherein a partition, which surrounds each of the terminals and surrounds the nano-silver paste, is formed on the package substrate.

3. The SAW device package of claim 2, wherein the partition is formed of an insulating material.

4. The SAW device package of claim 2, further comprising a molding portion which covers the SAW device, wherein the partition surrounds each of the plurality of terminals and the nano-silver paste simultaneously while surrounding a space, in which the IDT electrode is disposed, in order to prevent a molding material forming the molding portion from passing through the space in which the IDT electrode is disposed.

5. The SAW device package of claim 1, wherein the package substrate is an organic substrate.

6. A method of manufacturing an SAW device package, comprising:
preparing a SAW device package which comprises a piezoelectric substrate and comprises an IDT electrode and a plurality of electrodes, which are formed on the piezoelectric substrate;
preparing a package substrate which comprises a plurality of terminals respectively corresponding to the plurality of electrodes;
applying a nano-silver paste to each of the plurality of terminals of the package substrate;
placing the SAW device on the package substrate such that the plurality of electrodes come into contact with the nano-silver paste; and
curing the nano-silver paste by applying heat thereto.

7. The method of claim 6, further comprising forming a partition, which surrounds each of the plurality of terminals, on the package substrate, wherein the applying of the nano-silver paste comprises applying the nano-silver paste such that the nano-silver paste is surrounded by the partition.

8. The method of claim 7, wherein the partition is formed of an insulating material.

9. The method of claim 7, further comprising forming a molding portion which covers the SAW device, wherein the forming of the partition comprises forming the partition to surround each of the plurality of terminals simultaneously while surrounding a space, in which the IDT electrode is disposed, in order to prevent a molding material forming the molding portion from passing through the space in which the IDT electrode is disposed.

10. The method of claim 6, wherein the package substrate is an organic substrate.
